(19) United States
(12) Patent Application Publication
(10) Pub. No.: US 2006/0027450 A1
(43) Pub. Date: Feb. 9, 2006

(54) Arrangement and method for the production of gas-impermeable layers

(76) Inventors: Thomas Hegemann, Freigericht (DE); Elisabeth Sommer, Alzenau (DE)

Correspondence Address: FULBRIGHT & JAWORSKI, LLP, 666 FIFTH AVE, NEW YORK, NY, 10103-3198, US

(21) Appl. No.: 10/968,838

(22) Filed: Oct. 19, 2004

(30) Foreign Application Priority Data
Aug. 6, 2004 (EP) 04 018 645.4

(51) Int. Cl. C23C 14/34

(52) U.S. Cl. 204/192.14; 204/192.15; 204/192.12; 204/298.07; 428/35.1

(57) ABSTRACT

An arrangement and a method for the production of gas-impermeable layers, in particular for the coating of gas-permeable synthetic material substrates. With the aid of this arrangement or of the method light-permeable as well as also light-impermeable gas-blocking layers are produced using only one sputtering installation. A simple change-over switching from one gas supply, for example argon, to a second gas supply, for example argon, oxygen and nitrogen is carried out or the converse.

### FIELD OF THE INVENTION

This application claims priority from European Patent Application No: 04 018 645.4 filed Aug. 6, 2004, which is incorporated herein in reference in its entirety.

The invention relates to an arrangement and a method for the production of a transparent gas-impermeable coating.

### BACKGROUND AND SUMMARY OF THE INVENTION

As a rule, containers of synthetic materials are not entirely gastight, which has a negative effect in gas-containing beverage containers—for example lemonade or beer cans containing carbonic acid—in so far as the carbonic acid gradually escapes from the container through diffusion, since the carbon dioxide concentration inside the container is greater than outside of the container. For example, if a PET bottle (PET=polyethylene terephthalate) were to be filled exclusively only with carbon dioxide, the diffusion process would terminate only when the concentrations of the gas mixture inside and outside of the bottle are the same. Since not only carbon dioxide escapes from the bottle, but oxygen and nitrogen also diffuse into the bottle, after a sufficient length of time the bottle would be filled with the same gas mixture as is contained in the ambient air. If the bottle were to be filled with an excess CO₂ pressure, at the end of this process it would have an underpressure and the outside air pressure would compress the bottle. To prevent the carbonic acid or water vapor from escaping and oxygen from penetrating, the synthetic bottles are provided with a gas barrier.

However, these gas barriers have the disadvantage that they often crack if the coated container expands or shrinks.

A layer system for synthetic bodies is already known, which includes an acrylate layer applied directly on the synthetic body. On this acrylate layer is applied a layer of gas-impermeable material, on which, in turn, is applied an acrylate layer (U.S. Pat. No. 6,231,939). By utilizing two acrylate layers, in which the gas-impermeable material is embedded, the total coating acquires a certain elasticity. As the gas-impermeable metal is utilized silicon oxide, aluminum oxide or the metal.

However, of disadvantage is here that the gas-impermeable layer is relatively thick and therewith, if it consists of metal, is opaque and relatively inelastic.

The invention addresses the problem of applying a transparent and gastight coating by means of a sputtering arrangement onto a substrate of a synthetic material and to produce a reflecting barrier layer with the same sputtering arrangement.

This problem is solved according to the present invention.

Consequently, the invention relates to an arrangement and a method for the production of gas-impermeable layers, in particular for the coating of gas-permeable synthetic substrates. With the aid of this arrangement or this method it is possible to produce light-permeable as well as also light-impermeable gas-blocking layers using only one sputtering installation. In this method a simple switching takes place from one gas supply, for example argon, to a second gas supply, for example argon, oxygen and nitrogen, or conversely.

The advantage attained with the invention comprises in particular that through the use of aluminum as sputtering material a clear as well as also an opaque barrier layer can be generated with the same sputter installation. In addition, using aluminum oxynitride as the barrier layer makes possible recycling the coated substrates. Moreover, the coated substrates withstand pasteurization processes. The coating is furthermore elastic, in order to endure the shrinking process during the hot-bottling of PET bottles as well as also the expansion of bottles under pressure without cracks forming.

An embodiment example of the invention is shown in the drawing and will be described in further detail.

### BRIEF DESCRIPTION OF THE DRAWINGS

FIG. 1 shows a coating according to the invention on a substrate.

FIG. 2 shows a synthetic bottle with an outer coating.

FIG. 3 depicts a sputter installation for coating synthetic bottles.

### DETAILED DESCRIPTION

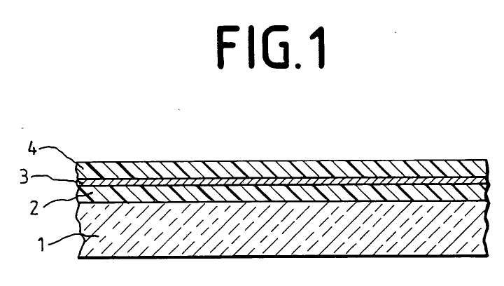

FIG. 1 shows a cutout of a substrate 1, which is provided with a coating. The substrate 1 is, for example, a portion of a wall of a PET bottle. On this substrate 1 is disposed a 0.2 to 1.5 μm thick polymer layer 2, for example an acrylate layer, on which is applied a 1 to 100 nm thick aluminum oxynitride layer 3. Above this AlOₓN_{y} layer 3 is a further polymer layer 4 having a thickness of 0.2 to 1.5 μm, which can also be an acrylate.

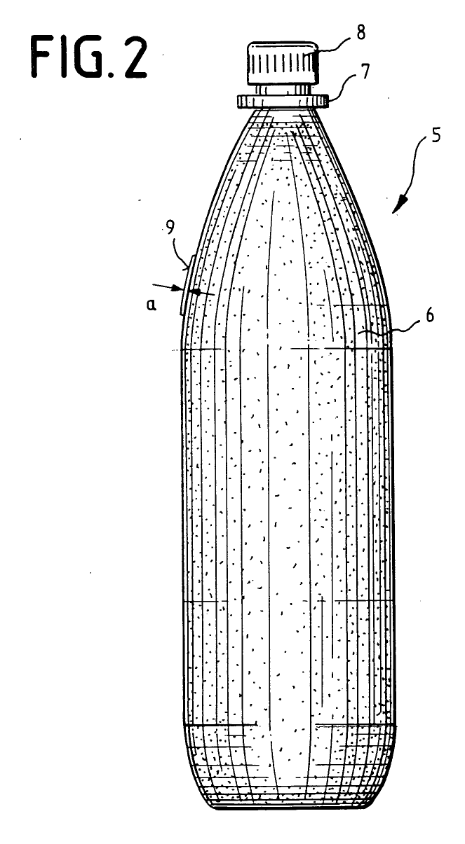

FIG. 2 shows a synthetic bottle 5, which consists of a receptacle 6 for a beverage, a collar 7 and a closure 8. The receptacle 6 and the collar 7 are, for example, comprised of PET and are clear. In order to secure this clear synthetic bottle 1 against gas diffusion, a coating 9 is applied over the entire receptacle 6 or over portions of this receptacle 6. This coating is only indicated in FIG. 1 on the outside of the receptacle 6 and has a thickness a representing the sum of the thicknesses of layers 2, 3, 4.

The aim is to make the coating 9 optionally translucent or opaque. A layer of AlOₓN_{y} is translucent, while a layer of Al is opaque.

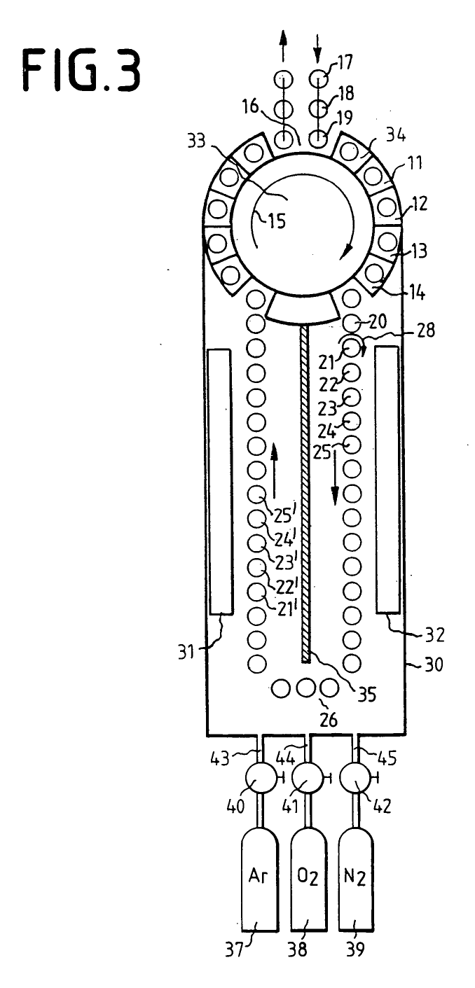

FIG. 3 depicts schematically an installation for coating synthetic bottles optionally with aluminum oxynitride or with aluminum as a barrier layer. A vacuum coating chamber 30 includes here on two sides at least one magnetron cathode 31, 32 each. Instead of a cathode, also several cathodes can be disposed one after the other on each side. The cathodes are equipped with an aluminum target. Between the cathodes 31, 32 additionally a partitioning wall 35 can also be provided. At the entrance to the vacuum coating chamber 30 is located an interlock chamber 33, which has several receiving chambers 34, 36, 11 to 14 disposed on an annulus. This interlock chamber 33 rotates in the clockwise direction, which is indicated by an arrow 15. At the entrance 16 of the interlock chamber 33 obtains atmospheric pressure. Here uncoated synthetic bottles 17, 18, 19 are placed onto a (not shown) linear conveying device, which subsequently transitions into an annular conveying device. The bottles located on the conveying device are hereby moved from the atmosphere into the high vacuum of the coating chamber 30. Here the bottles, of which some are provided with reference numbers 21 to 25, by rotation about their longitudinal axis, indicated by an arrow 28, are again transported to a (not shown) linear conveying device, with the aid of which they are guided past the magnetron cathode 32 or past a series of magnetron cathodes. From the aluminum targets of these magnetron cathodes metal particles are sputtered off, which subsequently react with oxygen and nitrogen. Hereby aluminum oxynitride is deposited on the outside wall of the bottles. All of the bottles in the vacuum coating chamber 30 rotate continuously about their longitudinal axis, and specifically at least at such a rate that a 360° rotation is completed before the bottle has moved passed a magnetron cathode 32. A more uniform distribution of the coating is obtained if the rotation of the bottle assumes a multiple of that cited. At the end 26 of the right-side coating path, the rotating bottles carry out an about-turn of 180 degrees and are now coated with aluminum oxynitride with the aid of magnetron cathode 31. The new positions of the bottles are denoted by 21′ to 25′.

The spaces between the partitioning wall 35 and the magnetron cathodes 31, 32 can be considered to be vacuum sputter chambers. At least one of these chambers has three gas inlets, through which, in addition to argon, also oxygen and nitrogen can be introduced.

In FIG. 3 three gas cylinders 37, 38, 39 with cut-off valves 40, 41, 42 are shown, which are connected to the sputter spaces via inlets 43, 44, 45. When the inlets 44, 45 of oxygen and nitrogen are shut, pure aluminum is deposited on the bottles. If it is prevented from oxidizing, this pure aluminum is reflective like silver. If all valves 40 to 42 are open, AlOₓN_{y} is formed and becomes deposited on the bottles. Instead of gas cylinders 38, 39, it is also possible to provide only one cylinder containing air can be provided. Air is composed of: 78.084% N₂ and 20.946% O₂.

Before the bottles are transported into the vacuum sputter chambers, they are provided with an acrylate layer. After the coating with the gas-impermeable layer Al or AlOₓN_{y}, a further acrylate layer is applied. The installation, in which the acrylate layers are applied, is not shown.

By utilizing aluminum as the sputtering material, decorative metallic as well as transparent barrier layers can be produced with the same coating device, and this can be accomplished without any change-over times. The light-permeable as well as also the light-impermeable layer can be generated by means of cost-effective DC sputtering.

AlOₓN_{y} layers having an approximate thickness of 4 nm are already sufficient to attain the necessary barrier properties. Such thin layers can be produced under extremely substoichiometric conditions without losing the necessary transparency and barrier properties. Herein x and y preferably fulfill the conditions 0<x<0.6 or 0<y<0.5, which can be achieved through the corresponding adjustment of the sputter parameters.

Instead of with the simple DC sputtering, the same layers—Al and AlOₓN_{y}—can also be produced with the technically more elaborate MF/RF sputter technique which, however, would markedly increase the cost of the coating.

In order to obtain these layers, the following sputter parameters were selected under laboratory conditions: as the gas flows 16 standard cubic centimeters air and 110 standard cubic centimeters argon at a pressure of 4×10⁻³ mbar. At an electric power of 500 W a synthetic bottle was coated, the bottle being rotating about its longitudinal axis, but not moved past the cathode.

Only the air gas flow was varied between 13 and 19 standard cubic centimeters. The composition of the air remained unchanged. The argon gas flow was adjusted between 80 and 140 standard cubic centimeter and the coating time was between 3 and 7 seconds. The sputtered-on layer thicknesses were between two and nine nanometer, and it was found that a layer thickness of at least six to seven nanometer was necessary to attain BIF values >5. By BIF value (BIF=Barrier Improvement Factor) is understood the ratio of the permeability of a substrate with coating to the permeability of a substrate without coating.

In production installations, as shown in FIG. 3 and which are intended to coat approximately 20000 bottles per hour, the coating time is reduced to approximately 5.55 seconds. For this purpose, the sputtering power can be raised to 630 W in order for the product of coating time and cathode power to remain constant and, consequently, as a first approximation, the same layer thickness to be deposited. Since, in contrast to the laboratory conditions, the production installation is a continuous pass installation, the coating here takes place dynamically, i.e. the substrate is moved past the cathode 32, 31 and therein simultaneously rotated about its longitudinal axis. Instead of increasing the sputtering power, it is also possible to utilize a longer cathode, such that the sputtering power of the laboratory test can be retained and the bottles are moved at a transport rate, which ensures that every 5.55 seconds a bottle is moved out of the installation through the interlock.

The distance between sputtering cathode 31, 32 and substrate 21-25; 21′-25′ also has an effect on the rate at which the layer grows. If this distance in the production installation differs from that of the laboratory installation, the power must be adapted correspondingly. A greater distance requires higher power and at a shorter distance it must be reduced.

The ratio of argon to air in the production installation is similar to that in the laboratory installation, but the precise gas flows depend on the installation conductance and on the evacuation capacity. The installation conductance depends on the internal structure, which, in a production installation, is determined by different requirements than in a laboratory installation.

The coating has been described above in connection with the coating of bottles. However, it is understood that in the same manner films and other web material can also be coated. Appropriate web coating installations are already known, cf. EP Application 04 012 165.9. Instead of two gas cylinders 38, 39 with O₂ or N₂ or one cylinder containing both gases, it is also possible to access the ambient air directly and to omit cylinders 38, 39 entirely. In this case the second gas container is the ambient air.

1-20. (canceled)

21. An arrangement for the production of gas-impermeable layers, in particular for the coating of gas-permeable synthetic material substrates, comprising:
a) a vacuum sputtering chamber having at least one target of aluminum, and
b) at least two gas containers, which are connected with the vacuum sputtering chamber via at least one gas inlet line, which can be shut.

22. An arrangement as claimed in claim 21, wherein a first gas container contains argon and a second gas container contains air.

23. An arrangement as claimed in claim 21, wherein three gas containers are provided, the first gas container containing argon, the second gas container containing oxygen and the third gas container containing nitrogen.

24. An arrangement as claimed in claim 21, wherein all of the two or three gas inlet lines are open.

25. An arrangement as claimed in claim 21 wherein only the gas inlet line for argon is open.

26. An arrangement as claimed in claim 24, wherein a switch-over device is provided, with which it is possible to switch between the supply of argon and the supply of argon, oxygen and nitrogen.

27. An arrangement as claimed in claim 21, wherein the synthetic material substrate is a hollow body.

28. A method for the production of a gas-impermeable layer, comprising the steps of:
a) providing an aluminum target in a vacuum chamber,
b) introducing argon into the vacuum chamber as the sputter gas and oxygen and nitrogen as reactive gases,
c) sputtering the aluminum target is.

29. A method for the production of a gas-impermeable layer, comprising the steps of
a) providing an aluminum target in a vacuum chamber,
b) introducing argon into the vacuum chamber as the sputter gas, and
c) sputtering the aluminum target.

30. The method as claimed in claim 28, further comprising introducing air into the vacuum chamber as the reactive gas.

31. The method as claimed in claim 28, wherein the operating parameters of the sputtering process are set such, that a transparent, gas-impermeable coating of AlOₓN_{y} is generated, in which 0<x<0.6 and 0<y<0.5.

32. The method as claimed in claim 29, wherein the operating parameters of the sputtering process are set such that an opaque coating of Al is generated.

33. The method as claimed in claim 31, wherein the AlOₓN_{y} layer is 1 to 100 nm thick.

34. The method as claimed in claim 31, wherein the AlOₓN_{y} layer is embedded between polymer layers.

35. The method as claimed in claim 34, wherein the polymer layers are acrylate layers having a thickness of 0.2 to 1.5 μm.

36. The method as claimed in claim 28, wherein the reactive gas contains approximately 65% to 90% nitrogen and approximately 10% to 35% oxygen.

37. The method as claimed in claim, 28, wherein the reactive gas contains more than 50% of nitrogen.

38. The method as claimed in claim 34, wherein the polymer layers comprise canonically polymerizing material of a thickness of 0.2 to 1.5 μm.

39. A gas-blocking coating for hollow bodies with a gas-permeable wall, wherein the gas-blocking coating contains at least one layer of AlOₓN_{y} where 0<x<0.6 and 0<y<0.5.

40. A gas-blocking coating for hollow bodies with a gas-permeable wall, wherein the gas-blocking coating comprises at least one layer of Al.
